(19) United States
(12) Patent Application Publication
(10) Pub. No.: US 2007/0190795 A1
(43) Pub. Date: Aug. 16, 2007

(54) Method for fabricating a semiconductor device with a high-K dielectric

(76) Inventors: Haoren Zhuang, Hopewell Junction, NY (US); Jiang Yan, Newburgh, NY (US); Jin-Ping Han, Fishkill, NY (US); Jingyu Lian, Hopewell Junction, NY (US); Alois Gutmann, Poughkeepsie, NY (US)

Correspondence Address: SLATER & MATSIL LLP, 17950 PRESTON ROAD, SUITE 1000, DALLAS, TX, 75252, US

(21) Appl. No.: 11/352,565

(22) Filed: Feb. 13, 2006

(51) Int. Cl. H01L 21/302

(52) U.S. Cl. 438/722; 438/591; 438/706; 438/710; 438/720

(57) ABSTRACT

Method for fabricating semiconductor devices with high-K materials without the presence of undesired formations of the high-K material. A preferred embodiment comprises forming a layer of material over a layer of a high-K material, etching the layer of material to expose a portion of the high-K material, performing a CDE (Chemical Downstream Etch) to remove any residual material formed during the etching, and etching the layer of the high-K material into alignment with remaining portions of the layer of material. The removal of the residual material results in a predictable trimming of the high-K material so that the semiconductor device has predictable and consistent performance, which is not possible if the high-K material has unpredictable dimensions.

### TECHNICAL FIELD

The present invention relates generally to a method for semiconductor device fabrication, and more particularly to a method for fabricating semiconductor devices with high-K materials.

### BACKGROUND

The use of high dielectric constant (K) materials, also known as high-K materials, has permitted a continued reduction in semiconductor device feature size. With the constant reduction in feature size, materials that have been used as gate insulators, such as silicon oxide, have capacitances too low to function adequately as insulators and electrons can readily leak through. High-K materials, with their higher dielectric constants, can provide a sufficient barrier to electron flow, even when small (thin) amounts of the materials are used as the gate insulator. The use of high-K materials as gate insulators requires the use of fabrication techniques that are more complex than those used in the fabrication of gate insulators from silicon oxide. These techniques include polycontact overetch (PC OE) and polycontact reactive ion etch (PC RIE).

With reference now to FIG. 1a, there is shown a diagram illustrating a cross-sectional view of a portion of an exemplary semiconductor device 100 after a PC OE, wherein a high-K material is used as a gate insulator. The semiconductor device 100 includes an oxide layer 105 created from a material such as silicon dioxide (SiO₂) formed on a silicon substrate 110. On top of the oxide layer 105 can be a high-K layer 115 created from a material such as NOₓ or HfO₂. Then, formed on the high-K layer 115 is a polysilicon layer, poly 120, creating the gate. The PC OE, used to create the gate, may result in the formation of some residual material (residue 125) that may remain on the high-K layer 115 and adhered to the poly 120. After the PC OE, the PC RIE can be used to prepare undesired portions of the high-K layer 115 and the oxide layer 105 for removal. However, the residue 125 covers certain portions of the high-K layer 115 and will protect those portions of the high-K layer 115 from the PC RIE. The PC RIE can remove materials such as silicon oxide residual material.

With reference now to FIG. 1b, there is shown a diagram illustrating a cross-sectional view of a portion of the semiconductor device 100 after a diluted hydrofluoric acid (DHF) wet clean. The DHF wet clean is able to remove the residue 125 (FIG. 1a) and portions of the high-K layer 115 and the oxide layer 105 that were exposed to the PC RIE. However, portions of the high-K layer 115 and the oxide layer 105 that were under the poly 120 and the residue 125 are not removed by the DHF wet clean since they were not exposed to the PC RIE. The portion of the high-K layer 115 and the oxide layer 105 that extends out from beneath the poly 120 due to the presence of the residue 125 forms a foot 150. The diagram labels the foot 150 as being on the left side of the poly 120. However, the foot 150 may also be present on the right side of the poly 120. The foot 150 can form wherever there was residue from the PC OE. The dimensions of the foot 150 can vary depending upon the amount of residue 125 remaining from the PC OE. In some instances, there may not be any residue 125 from the PC OE.

With reference now to FIG. 2, there is shown a diagram illustrating a sequence of events 200 in the fabrication of a semiconductor device, wherein the semiconductor device makes use of high-K materials. The sequence of events 200 shows the events in the fabrication of the semiconductor device that involve the removal of undesired portions of the high-K materials from an semiconductor device. Other events in the fabrication of the semiconductor device occurring before and after the removal of the undesired portions of the high-K materials are not shown in the sequence of events 200. Once the poly, such as the poly 120 (FIG. 1a) is formed over a layer of high-K material, such as the high-K layer 115 (FIG. 1a), excess high-K material can be removed. Portions of the high-K layer 115 not lying underneath the poly 120 should be removed, along with portions of an oxide layer, such as the oxide layer 105 (FIG. 1a). A polycontact reactive ion etch (PC RIE) can be used to remove certain materials formed by previous fabrication processes that are no longer needed, portions of materials that are needed but due to fabrication process technology limitations more material than needed was formed, and so forth (block 205).

However, a side effect of the PC RIE can be the formation of residual material, such as residue 125 (FIG. 1a). The presence of the residue 125 can prevent the transformation of portions of the high-K layer 115 laying underneath the residue 125. Since the formation of the residue 125 as well as the amount of residue formed is unpredictable, the amount of the high-K layer 115 being covered by the residue 125 is unpredictable. This unpredictability can lead to undesired behavior in the semiconductor device. This unpredictability can lead to undesired behavior in the semiconductor device since critical dimensions, such as gate length, are not consistent or predictable.

A resist strip operation can be used to remove the remaining photoresist material present on the surface of the semiconductor device, for example, the photoresist material used to create the gate (block 210). After the resist strip, a cleaning operation using diluted hydrofluoric acid (DHF) can be used to remove the residue 125, portions of the high-K material, and portions of an oxide layer, such as the oxide layer 105 (FIG. 1a), underneath it (block 215). Portions of the high-K layer 115 and the oxide layer 105 that were masked by the residue 125 are not removed by the DHF and form a foot, such as the foot 150 (FIG. 1b).

One disadvantage of the prior art is that the dimensions of the foot 150 (or even its presence) cannot be accurately predicted. The foot 150 may be small or large for some transistors, while the foot 150 may not even be present in other transistors. This uncertainty can lead to unexpected performance and operation in the semiconductor device, i.e., poor critical dimension (CD) control and electrical performance.

Another disadvantage of the prior art is that recesses can form in the silicon substrate, which can further affect subsequent integrated fabrication processes.

### SUMMARY OF THE INVENTION

These and other problems are generally solved or circumvented, and technical advantages are generally achieved, by preferred embodiments of the present invention which provides a method for fabricating semiconductor devices with high-K materials with the presence of undesired formation.

In accordance with a preferred embodiment of the present invention, a method for fabricating a semiconductor device is provided. The method includes forming a layer of material over a layer of a high-K material and etching the layer of material to expose a portion of the high-K material. The method also includes performing a chemical downstream etch to remove any residual material formed during the etching of the layer of material. The method further includes etching the layer of the high-K material into alignment with remaining portions of the layer of material.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### DESCRIPTION OF THE DRAWINGS

For a more complete understanding of the present invention, and the advantages thereof, reference is now made to the following descriptions taken in conjunction with the accompanying drawings, in which:

FIGS. 1a and 1b are cross-sectional views of portions of exemplary semiconductor devices with a high-K material used as a gate insulator;

FIG. 2 is a diagram of a sequence of events in the fabrication of a semiconductor device, wherein the semiconductor device makes use of high-K materials;

FIG. 3 is a diagram of a chemical downstream etch apparatus, according to a preferred embodiment of the present invention;

FIGS. 4a through 4e are diagrams of cross-sectional views of a portion of a semiconductor device during a fabrication of the semiconductor device, according to a preferred embodiment of the present invention; and

FIG. 5 is a diagram of a sequence of events in the fabrication of a semiconductor device, wherein the semiconductor device makes use of high-K materials and a chemical downstream etch process is used to prevent the formation of a high-K foot in the semiconductor device, according to a preferred embodiment of the present invention.

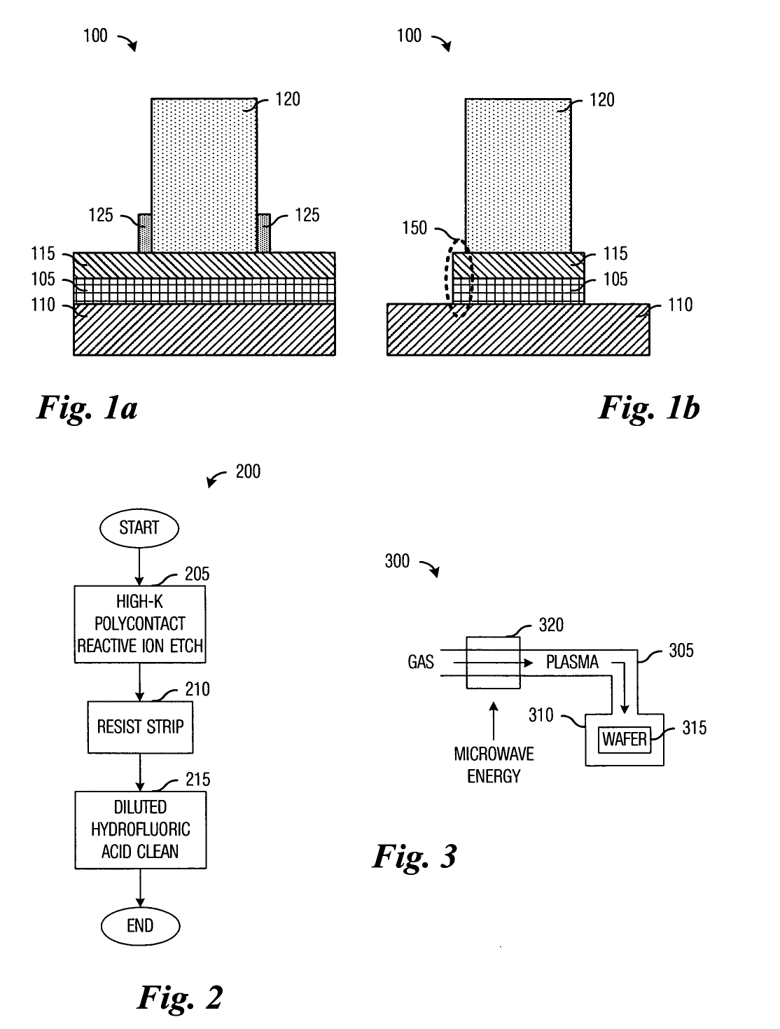

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a method for fabricating semiconductor devices, such as integrated circuits, with high-K materials without the presence of undesired formations of the high-K material.

With reference now to FIG. 3, there is shown a diagram illustrating a chemical downstream etch (CDE) apparatus 300, according to a preferred embodiment of the present invention. In a CDE, a semiconductor wafer 315 is exposed to a gas/plasma atmosphere under a certain pressure range and a temperature range for a certain time range. The exposure to the gas/plasma atmosphere can result in the effective removal of residual materials, such as those left by a PC OE operation. Additionally, the CDE can have high selectivity to various oxides, such as silicon oxide.

The CDE apparatus 300 can include a gas/plasma delivery tube 305, wherein a gas, such as a gas combination of oxygen (O₂) and tetrafluoromethane (CF₄) can be injected at a certain concentration, pressure, flow rate, and so forth, into a process chamber 310. In the process chamber 310 can be a semiconductor wafer 315. In addition to CF₄, other gasses such as octafluorocyclobutane (C₄F₈) or trifluoromethane (CHF₃) can also be used in conjunction with O₂. In general, CₓF_{y} and CHₓF_{y} can be used in conjunction with O₂ in the CDE. The process chamber 310 may contain more than one semiconductor wafer. A pump (not shown) can be used to evacuate the process chamber 310 of the gas combination in order to maintain a proper concentration, pressure, flow rate, and so on. A reaction chamber 320 that is bombarded with a microwave energy, for example, can be used to energize the gas to create a plasma of ions that will be used to etch the semiconductor wafer 315. The gas can be energized into a plasma by a high power microwave or radio frequency (RF) energy source, for example.

For effective removal of residual materials, such as the residue 125 (FIG. 1a), a preferred set of process parameters for the CDE apparatus 300 can include: a gas flow ratio, for example, with O₂/CF₄, range from 10 to 30, a temperature range from 50 to 70 degrees Celsius, a process time of greater than 60 seconds, and a plasma power source of greater than 200 Watts.

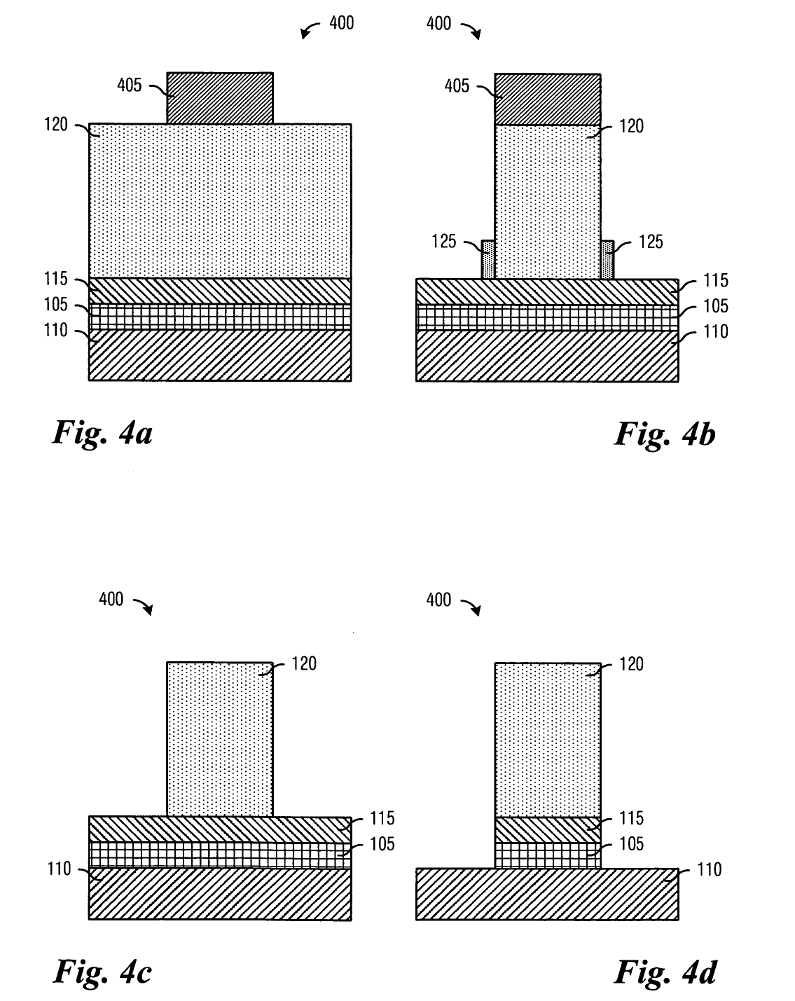

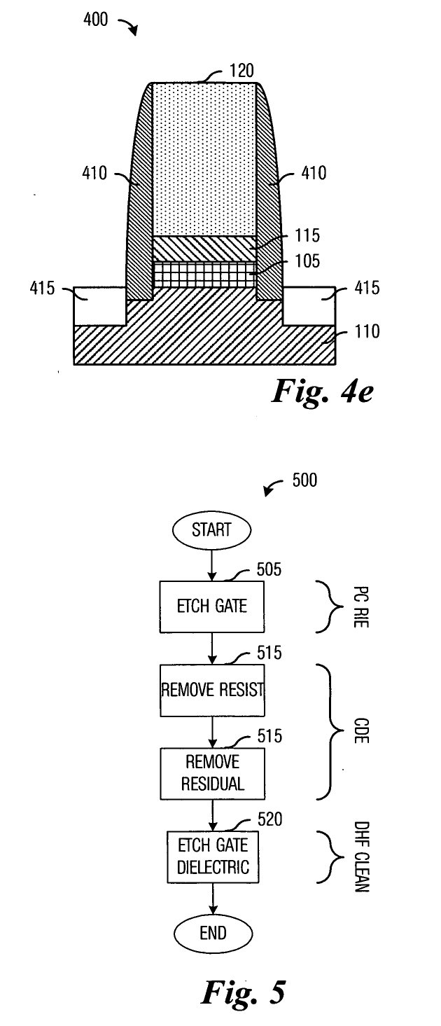

With reference now to FIGS. 4a through 4e, there are shown diagrams illustrating exemplary cross-sectional views of a portion of a semiconductor device 400 during a fabrication of the semiconductor device 400, wherein the semiconductor device 400 contains high-K materials and a CDE process is used to prevent the formation of high-K foot in the semiconductor device 400, according to a preferred embodiment of the present invention. The diagram shown in FIG. 4a illustrates the semiconductor device 400 after a photoresist layer (not shown) has been exposed and portions of the photoresist layer has been removed, leaving a portion of the photoresist (resist block 405) to be used as a mask to create a gate for the semiconductor device 400. PC RIE processing can be used to remove portions of the poly 120 that is not covered by the resist block 405.

The diagram shown in FIG. 4b illustrates the semiconductor device 400 after the semiconductor device 400 has undergone PC RIE processing. The PC RIE processing removes portions of the poly 120 not covered by the resist block 405 while leaving the resist block 405 as well as the oxide layer 105 that is formed on a substrate, such as a silicon substrate 110, and the high-K layer 115. However, the PC RIE processing can leave a residual material, such as residue 125 that can form adjacent to the poly 120 and on top of portions of the high-K layer 115.

The diagram shown in FIG. 4c illustrates the semiconductor device 400 after the semiconductor device 400 has undergone CDE processing. After PC RIE processing (shown in FIG. 4b), residual material resulting from the PC RIE processing, shown as residue 125, may create problems in further fabrication and operation of the semiconductor device 400. Therefore, any residual material should be removed from the semiconductor device 400 prior to the semiconductor device 400 undergoing additional fabrication. The CDE processing removes the residual material, such as the residue 125, as well as the resist block 405, and results in the semiconductor device 400 being ready for further processing.

The diagram shown in FIG. 4d illustrates the semiconductor device 400 after the semiconductor device 400 has undergone DHF cleaning. The DHF cleaning strips away portions of the high-K layer 115 and the oxide layer 105 not covered by the poly 120. Since the residual material (the residue 125 (FIG. 4b)) and the resist block 405 (FIG. 4b) have been removed by the CDE processing, the high-K layer 115 and the oxide layer 105 are removed and are in alignment with the poly 120, for example. Therefore, the high-K layer 115 and the oxide layer 105 are trimmed to precise and predictable dimensions, which can lead to improved fabrication quality and subsequent semiconductor device performance.

The diagram shown in FIG. 4e illustrates the semiconductor device 400 after the semiconductor device 400 has undergone additional processing to complete the fabrication of the semiconductor device 400. The completed semiconductor device 400 includes gate spacers 410 and drain and source regions 415.

With reference now to FIG. 5, there is shown a diagram illustrating a sequence of events 400 in the fabrication of a semiconductor device, wherein the semiconductor device contains high-K materials and a CDE process is used to prevent the formation of a high-K foot in the semiconductor device, according to a preferred embodiment of the present invention. The sequence of events 500 shows the events in the fabrication of the semiconductor device that involve the removal of undesired portions of the high-K materials from a semiconductor device without the formation of a high-K foot. Other events in the fabrication of the semiconductor device occurring before and after the removal of the undesired portions of the high-K materials are not shown in the sequence of events 500. Once the poly, such as the poly 120 (FIG. 4a) is formed over a layer of high-K material, such as the high-K layer 115 (FIG. 4a), the gate of the semiconductor device can be created, for example, by etching with PC RIE processing (block 505).

Once the gate of the semiconductor device has been created (block 505), resist blocks, such as resist block 405 (FIG. 4a), used in the creating of the gate can be removed (block 510). As discussed previously, the PC RIE processing used to create the gate can result in the formation of some residual material. The residual material can negatively impact the trimming of the high-K material in subsequent processing. Therefore, the residual material should also be removed (block 515). According to a preferred embodiment of the present invention, both the resist blocks and the residual material can be removed using CDE processing, such as in the CDE apparatus 300 (FIG. 3). The CDE processing can follow the process parameters outlined above, with a preferred set of process parameters being as follows: a gas that is a combination of O₂ and CF₄ in an O₂ to CF₄ ratio of 950 to 70 standard cubic centimeters per minute (SCCM) (or a ratio of approximately 13.5) at a pressure of approximately 28 Pascal (Pa) with a plasma power source of approximately 700 Watts for about 180 seconds.

After undergoing the CDE processing, the gate dielectric of the semiconductor device can be cleaned (etched or trimmed) using a diluted hydrofluoric acid (DHF) cleaning process (block 520). The cleaning by DHF can effectively trim away portions of the gate dielectric that is no longer desired on the semiconductor device. According to a preferred embodiment of the present invention, the gas used in the CDE processing produces plasma that is reactive to the residual material from the PC RIE and the CDE processing removes any residual material left from the PC RIE, without removing or altering any other materials and layers present in the semiconductor device, while the DHF cleaning process removes portions of the high-K layer 115 and the oxide layer 105 not directly underneath the poly 120.

An advantage of a preferred embodiment of the present invention is that the removal of residual removal can prevent the formation of a high-K foot and produce a semiconductor device with more predictable performance.

A further advantage of a preferred embodiment of the present invention is that the CDE processing does not result in recesses in the silicon substrate, which can lead to performance and fabrication difficulties.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for fabricating a semiconductor device, the method comprising:
forming a layer of material over a layer of a high-K material;
etching the layer of material to expose a portion of the high-K material;
performing a chemical downstream etch thereby removing any residual material formed during the etching; and
etching the layer of the high-K material in alignment with remaining portions of the layer of material.

2. The method of claim 1, wherein the etching the layer of material comprises etching a polysilicon layer using a reactive ion etch.

3. The method of claim 1, wherein the chemical downstream etch comprises a plasma etch utilizing a combination gas comprised of oxygen and at least one gas selected from the group consisting of tetrafluoromethane (CF₄), octafluorocyclobutane (C₄F₈), and trifluoromethane (CHF₃).

4. The method of claim 3, wherein the combination gas is injected in an oxygen-to-tetrafluoromethane gas ratio of approximately 13.5 at a pressure of about 28 Pa and a gas-to-plasma energizing power source of approximately 700 Watts for about 180 seconds.

5. The method of claim 1, wherein the chemical downstream etch comprises a plasma etch utilizing a gas including oxygen (O₂) and tetrafluoromethane (CF₄).

6. The method of claim 5, wherein the gas is injected in an oxygen-to-tetrafluoromethane gas ratio ranging from about 10 to about 30.

7. The method of claim 6, wherein the chemical downstream etch is performed at a temperature in the range of about 50 to about 70 degrees Celsius.

8. The method of claim 6, wherein the chemical downstream etch is performed for a duration that is greater than about 60 seconds.

9. The method of claim 6, wherein a microwave power source is used to energize the gas into the plasma, and wherein the power source is greater than about 200 Watts.

10. The method of claim 1, wherein etching the layer of the high-K material comprises performing a diluted hydrofluoric acid clean.

11. The method of claim 10, wherein forming a layer of material comprises depositing a layer of polysilicon.

12. A method of forming a transistor device, the method comprising:
forming a gate dielectric over a semiconductor body, an upper surface of the gate dielectric layer comprising a high-K dielectric material;
forming a conductive layer over the gate dielectric;
performing a first etch to pattern the conductive layer into a gate electrode;
performing a second etch to remove any residual material formed along sidewalls of the gate electrode during the etching; and
performing a third etch to pattern the gate dielectric layer in alignment with the gate electrode, wherein the first etch, the second etch and the third etch comprise separate etching processes.

13. The method of claim 12, wherein the second etch comprises a chemical downstream etch that is performed with a plasma.

14. The method of claim 13, wherein the second etch uses a combination gas comprised of oxygen (O₂) and tetrafluoromethane (CF₄).

15. The method of claim 12, wherein forming a gate dielectric layer comprises forming an oxide layer over the semiconductor body and forming a high-K dielectric layer over the oxide layer.

16. The method of claim 15, wherein the high-K dielectric layer comprises NOₓ or HfO₂.

17. A method of making a transistor device, the method comprising:
forming a gate dielectric over a semiconductor body;
forming a conductive layer over the gate dielectric;
etching the conductive layer to form a gate electrode;
performing a chemical downstream etch to remove any residual material formed along sidewalls of the gate electrode during the etching; and
etching the gate dielectric layer in alignment with the gate electrode, the etching of the gate dielectric layer being performed in a separate process than the chemical downstream etch.

18. The method of claim 17, wherein the gate dielectric comprises a high-K dielectric.

19. The method of claim 18, wherein performing a chemical downstream etch comprises performing a plasma etch using a combination gas comprised of oxygen (O₂) and tetrafluoromethane (CF₄).

20. The method of claim 18, further comprising forming source/drain regions in the semiconductor body adjacent to edges of the gate electrode.
